(19) United States
(12) Patent Application Publication
(10) Pub. No.: US 2002/0110955 A1
(43) Pub. Date: Aug. 15, 2002

(54) Electronic device including at least one chip fixed to a support and a method for manufacturing such a device

(76) Inventors: Philippe Patrice, Marseille (FR); Jean-Christophe Fidalgo, Gemenos (FR); Bernard Calvas, Marseille (FR)

Correspondence Address: James A. LaBarre, BURNS, DOANE, SWECKER & MATHIS, L.L.P., P.O. Box 1404, Alexandria, VA, 22313-1404, US

(21) Appl. No.: 10/126,874

(22) Filed: Apr. 22, 2002

Related U.S. Application Data
(62) Division of application No. 10/009,496, filed on Dec. 13, 2001.
Application No. 10/009,496 is a 371 of international application No. PCT/FR00/01493, filed on May 30, 2000.

(30) Foreign Application Priority Data
Jun. 15, 1999 (FR) FR99/07550

(51) Int. Cl. H01L 23/495; H01L 21/44; H01L 21/48; H01L 21/50

(52) U.S. Cl. 438/106; 257/666

(57) ABSTRACT

The invention aims at the manufacturing of a device having a support associated with at least one microcircuit in the form of a chip, and comprises the replacement of at least one chip having a defect either within it or at its connection to the communication interface; provision is made for:

pressing the chip to be replaced into the thickness of the support so that the top surface of the chip fits flush with the surface (16a) of the support or is slightly recessed below it and its connection with the communication interface is broken;

providing an assembly composed of a thin replacement chip.

The invention relates to an electronic device including at least one chip fixed to a support and a method for manufacturing such a device.

In certain fields, such as the field of smart cards, it is necessary to mount a microcircuit or chip on a relatively thin flexible support. In the case of smart cards, it is necessary on the one hand for the presence of the chip not to cause a protrusion beyond a threshold established by international standards (currently fixed at 50 μm) and on the other hand for the mounting of the chip to be sufficiently secure to allow durable use even when the card is subjected to relatively high bending and twisting stresses.

Conventionally, creating an excessive protrusion is avoided by housing the chip in a cavity provided for this purpose in the thickness of the support.

FIG. 1 shows schematically a known example of mounting a chip on a support 16 intended to constitute a smart card. The chip is housed almost entirely in a cavity 30 so that its thickness is included within that of the support 16. The chip has a set of connection pads 8 on the edges of its surface turned towards the outside of the cavity 30. These pads 8 are connected to respective contacts 7 on the support by wires 9. The contacts 7 can be situated at the bottom of the cavity, or at an intermediate level in a recessed area 11 around the cavity, as in the example illustrated. These contacts 7 are in their turn electrically connected to contact areas 18a and 18b intended to allow an ohmic connection with a card reader. These contact areas are housed entirely in the recess 11 so that their thickness is also contained within that of the support 16.

To protect the whole, a coating of protective material 20 is formed, covering the entire zone occupied by the cavity 30, the wires 9 and a portion of the internal edges of the contact areas 18a and 18b.

This technique suffers from several drawbacks. Firstly, the operation consisting of electrically connecting the connection pads 8 of the chip 2 to the contact 7 requires the use of very fine and delicate wires 9, thus forming weak points. Moreover, the operations of soldering these wires 9 require a large amount of tooling and a not insignificant amount of time.

Moreover, the formation of the cavity 30 requires a machining step which is both expensive and weakening for the card.

It should also be noted that this technique based on the integration of a chip in a cavity in a support is difficult to use when it is necessary to collect together several components, for example several chips or other passive or active elements in the same support.

In the light of these problems, the invention proposes a novel approach for the manufacture of devices containing at least one chip mounted on a support.

Thus the objects of the invention are a manufacturing method and a device including a support associated with at least one chip, according to the following claims.

The invention in one example uses the technology of chips produced in a very thin substrate, such as that described notably in the patent document WO-A98/02921.

Creating at least part of the communication interface only after the attachment of a chip is particularly advantageous from the point of view of the methods for manufacturing such devices and the protrusion which the chip and interface assembly exhibits relative to the general plane of the face of the support.

Thus the invention makes it possible, in one example, for the second face to be attached to a surface portion of the face of the support which is substantially in the general plane thereof.

The document FR-A-2760113 can be cited, which describes the manufacture of a mixed card with and/or without contacts. The body of the card has an opening for housing a module. A last operation consists in removing an adhesive sheet then revealing bared contacts.

The document DE-A-19735170 describes a card with several chips, one of which is housed in a cavity. A copper frame is glued to the support and delimits a sealing material (by dam and fill).

The document FR-A-2747812 describes a card body, a circuit fixed in a cavity and an antenna deposited by screen printing on the body.

Note also that the document FR-A-2797203 describes a die attach where “a local heating of the cavity is carried out and then a fitting of the chip in the thermoplastic material thus material.” Equally, FR-A-2750250 describes a hot insertion of the chip in the module substrate, in the framework of its protection.

In one example, the chip is produced by so-called silicon on insulator (SOI) technology and has an overall thickness substantially equal to or less than 10 μm.

The invention lends itself particularly well to the production of devices containing several chips on the same support. In this case, the step of producing at least part of the communication interface can be performed simultaneously for at least one group amongst the plurality of chips.

According to another aspect of the invention, it is possible to repair a device by the replacement on the support of at least one chip having a defect within it, that is to say at its connection to the communication interface.

This is because the very slight thickness of the assembly consisting of chip plus communication interface obtained by virtue of the aforementioned method makes it possible to replace a defective chip by superimposing a replacement chip on top of the chip where the defect is situated.

The invention will be more clearly understood from a reading of the following description of non-limitative examples, with reference to the accompanying drawings, in which:

FIG. 1 is a view in section of a known smart card showing the location of a chip in a cavity in the support;

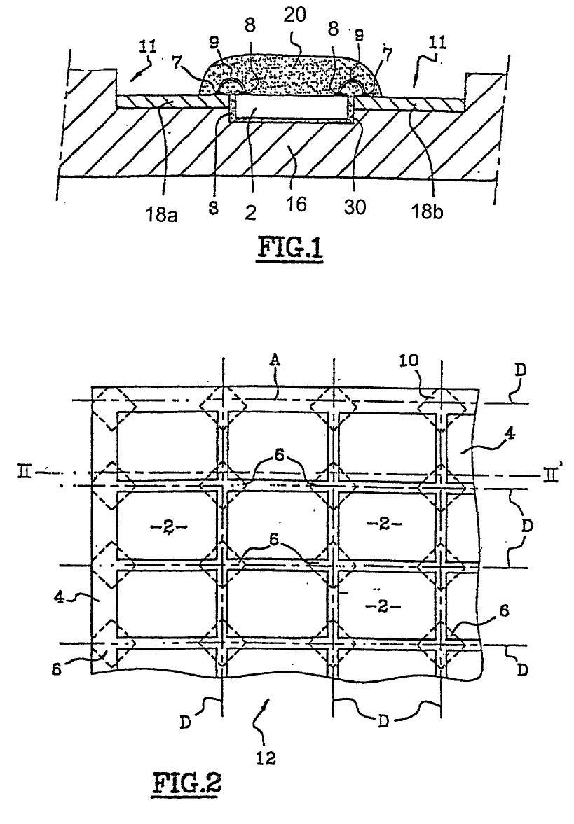

FIG. 2 is a partial plan view of a wafer resulting from the so-called silicon on insulator technology used in the embodiments of the invention;

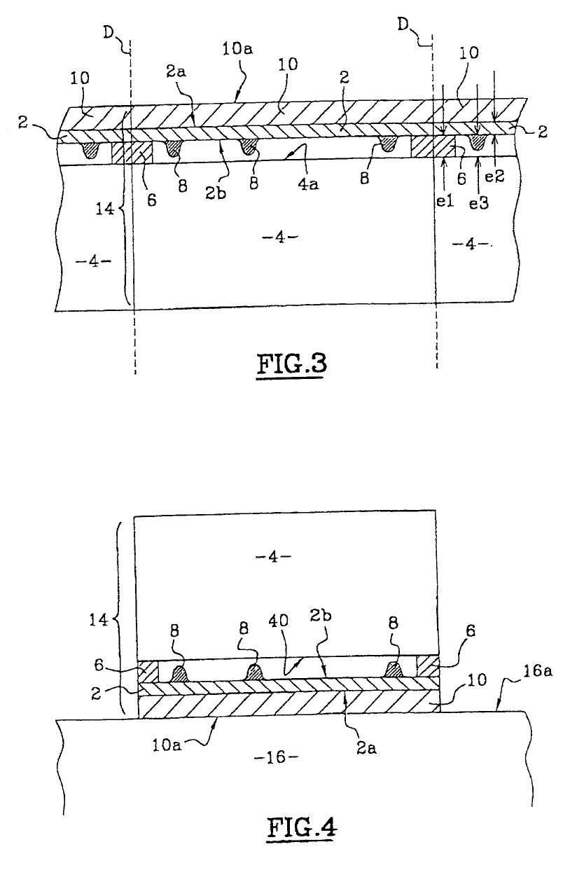

FIG. 3 is a view in section along the axis II-II′ in FIG. 2;

FIG. 4 is a view in section of an assembly comprising a chip cut from the wafer depicted in FIG. 2 and attached to a face of a support;

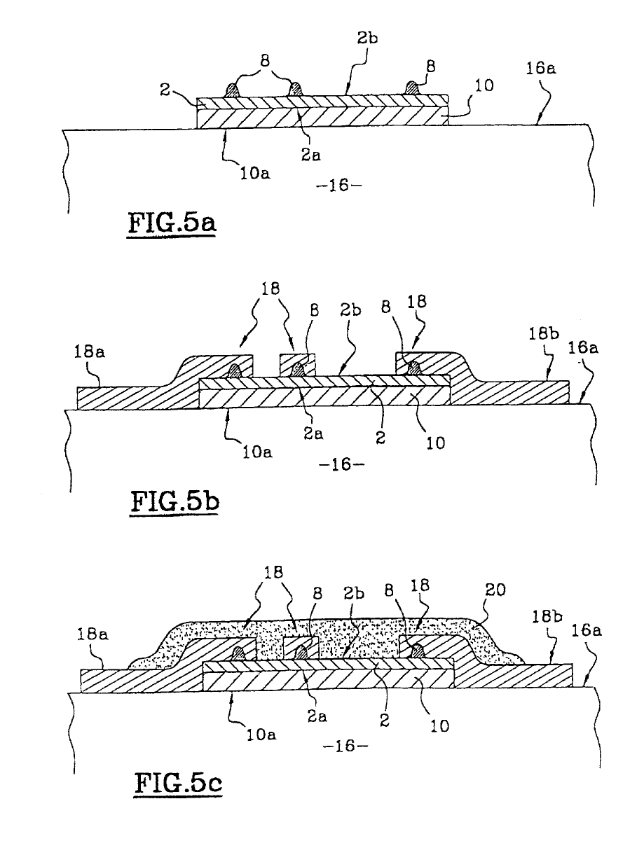

FIGS. 5a to 5c are views in section depicting different steps of the manufacture of a device according to a first embodiment of the invention;

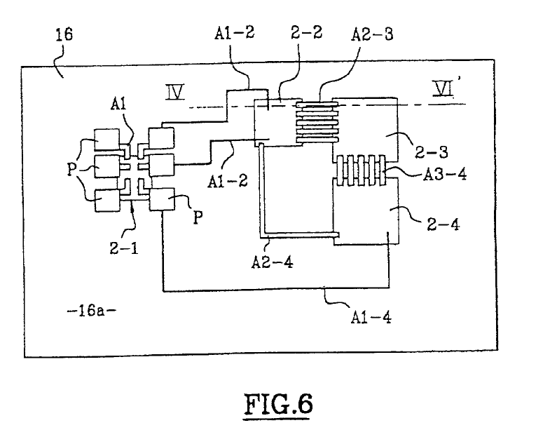

FIG. 6 is a plan view of a card containing several chips on the same face in accordance with a second embodiment of the invention;

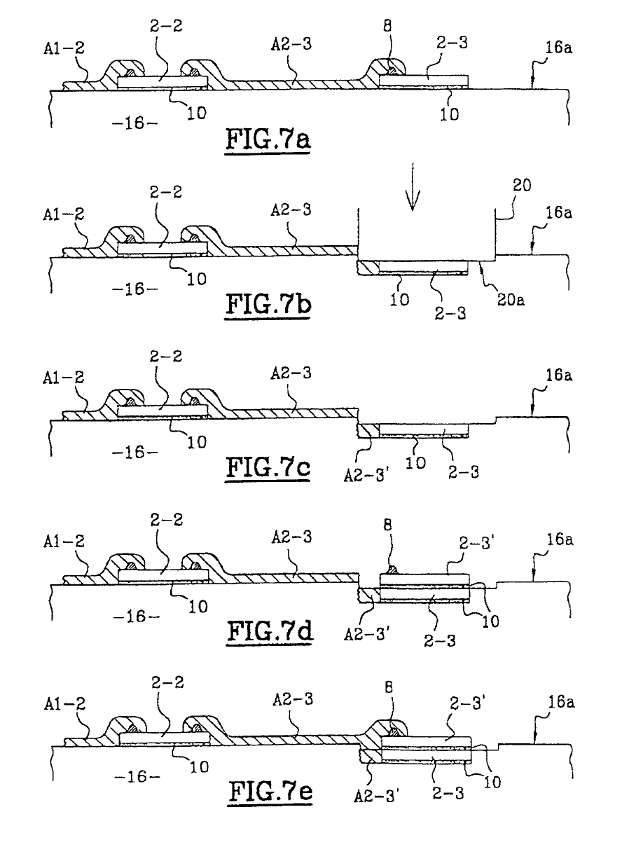

FIGS. 7a to 7e are views in section along the axis VI-VI′ in FIG. 6 depicting different steps of the repair of a device by chip replacement.

FIG. 2 shows a wafer 12 resulting from the so-called silicon on insulator technology (SOI). This technology makes it possible to produce chips 2—that is to say the active part of the microcircuit—which are very thin. The chips 2 are disposed in lines of rows on an insulating protective substrate 4, typically made from glass, which constitutes the body of the wafer. This insulating substrate 4 serves amongst other things to protect the chips 2, which are flexible because of their thinness (around 10 μm).

Each chip 2 is held on the substrate 4 by adhesive pads 6. These adhesive pads 6 consist of small rectangular areas, turned through 45° with respect to the sides of the chips 2 and placed on the respective corners of each chip, so that, apart from the periphery of the wafer 12, a pad 6 covers four joined corners of four different chips.

FIG. 3 is a partial view in section along the axis II-II′ in FIG. 2 which shows the structure of an assembly composed of a chip 2, an adhesive pad 6 and a glass substrate 4.

The chip 2 has, on one or more of its edges, electrical connection pads which make it possible to connect the circuit produced on the chip with the outside. Each connection pad 8 is produced by a protrusion, more generally known by the English term “bump”. The bumps 8 on the chip 2 constitute points protruding from one of the faces of the chip 2, allowing the necessary interconnections.

In accordance with the invention, the bumps 8 are formed on the face 2b of the chip 2 which is turned towards the protective glass substrate 4. Each protrusion 8 has a substantially ogival shape affording a good mechanical and electrical contact with a corresponding pad at its interface.

The thickness e1 of the adhesive pads 6 is sufficient for the top of the bumps 8 not to be in contact with the face 4a of the substrate 4 which is opposite it.

It should be noted that SOI technology currently makes it possible to produce chips 2 whose overall thickness is around 10 μm, or even substantially less. This dimension comprises on the one hand the thickness of the whole of the surface of the chip 2 and on the other hand the projections at the pads affording connection between the chip and the outside.

In the example depicted in FIG. 3, the thickness e2 of the body of the chip is for example around 10 μm and the relief e3 of the protrusions 8 is also around 5 μm.

The SOI technology making it possible to obtain chips with such dimensional characteristics is described notably in the document WO-A-98 02921 in the name of Kopin.

An adhesive layer 10 is applied to the wafer 12, before the latter is cut out, at the exposed face 2a of the chip 2, that is to say the face opposite to the one to be turned towards the protective substrate 4, as shown in FIG. 3.

Several techniques are possible for producing this adhesive layer 10.

According to a preferred embodiment of the invention, the adhesive layer is produced by the lamination of a fine film of hot-melt material.

In a variant, this layer 10 can be produced by screen printing using an adhesive lacquer which is reworkable at temperature, such as a thermoplastic or thermosetting material.

By way of example, the thickness of the adhesive layer 10, whatever the technique by means of which it is produced, is between m and n μm, a typical value being 10 μm.

Once the adhesive layer 10 has been deposited, the wafer 12 is cut along the interstices D between the lines and rows of chips (FIGS. 1 and 3) in order to obtain individual assemblies 14 each to the format of a chip 2 and composed of a glass substrate 4, adhesive pads 6 holding a chip 2 on the corners thereof and the adhesive layer 10 covering the whole of the chip.

It will now be described how at least one such assembly 14 allows the mounting of a chip or chips on one or each face of a thin support according to different embodiments.

In a first embodiment, described with reference to FIGS. 4 and 5a-5c, the assembly 14 is deposited on a flexible support 16 made from plastics material intended to constitute the body of a smart card to the conventional format established by ISO 7810. Typically, the support can be produced from ABS, PVC or PET resin.

In the example illustrated in FIG. 4, the body of the card 16 is intended to contain only one chip 2 on one 16a of its faces in order to form a so-called “card with contact”.

Firstly, the assembly 14 is offered up at the location of the support 16 reserved for the mounting of the chip in accordance with the aforementioned standard, with the adhesive layer 10 turned towards the face 16a intended to receive the chip 2. In this way, the assembly 14 is glued to the support 16 at the initially exposed face 10a of the adhesive layer 10 (FIG. 4).

Once the assembly 14 is fixedly adhered to the support 16, the protective substrate 4 is removed. This operation can be performed simply by peeling off the substrate 14. This is because the points of attachment of the substrate to the chip by the four adhesive pads 6 (one at each corner) are relatively weak and their rupture can be caused by pulling off without risk to the fixing, which is much more firm, of the adhesive layer 10 to the surface 16a of the support.

In addition, when the glass substrate 4 is removed, the adhesive pads 6 remain stuck to the latter and are therefore also removed from the surface 2b of the chip 2.

Therefore, after the removal of the substrate 4, the configuration of the chip 2 glued to one face 16a of its support 16 is obtained, with the bumps 8 turned towards the outside relative to this face 16a, as depicted in FIG. 5a.

It should be noted that the chip 2 is mounted, via the adhesive layer 10, directly on the principal face 16a of the support 16. In other words, no cavity or other recess is provided on the face 16a for housing the chip 2. Thus the adhesive layer 10 and the chip 2, as well as the bumps 8, protrude on the face 16a. In the example, the total thickness of the adhesive layer 10 and chip 2 does not exceed 20 microns.

Next, a communication interface 18 is printed on the exposed surface 2a of the chip 2 and its periphery (FIG. 5b). The communication interface 18 constitutes an electrically conductive layer with a pattern for connecting each bump 8 on the chip 2 to a contact area on the smart card.

In the example, the step of printing the communication interface 18 is performed in a single screen printing step by means of a composition containing conductive particles (silver, copper, nickel or other). This composition also contains adhesive material to afford good mechanical strength of the communication interface 18 on the chip 2 and its support 16. The communication interface 18 thus forms a layer divided on the general plane of the support 16 into several sections electrically insulated from each other. Each section covers a respective bump 8 and extends beyond one edge of the chip 2 in order to constitute, on the face 16a of the support 16, a corresponding contact area 18a, 18b, making it possible to engage with contacts on a reader. Thus each section of the printed communication interface 18 constitutes a point of contact with a bump 8, a contact area 18a, 18b and a current feed between the bump and the contact area.

In the example, the thickness of the printing layer 18 forming the communication interface is around 30 microns or less. In this way, the maximum protrusion on the smart card, situated at the stack consisting of the adhesive layer 10, the chip 2 and the layer of the communication interface 18, does not exceed 50 microns. Because of this, the card thus produced is in accordance with ISO 7810 concerning the acceptable protrusion.

It will be noted that the printing step produces all the components of the communication interface, namely: the connection with bumps 8 on the chip 2, the areas of contact 18a, 18b with a reader and the current feeds between each protrusion and its respective contact area. The contact areas 18a, 18b are produced so as to protrude directly on the face 16a of the support forming the smart card.

In a variant, it is possible to produce one or more of the aforementioned components of the communication interface at different steps.

Thus it is possible to print the connection areas 18a, 18b prior to the attachment of the chip 2 and its adhesive layer 10 on the support 16. In this case, the printing operation described with reference to FIG. 5b consists of printing only the connection with the bumps 8 on the chip 2 and the respective current feeds connecting these to the contact areas 18a, 18b previously printed on the support 16.

When the contact areas are thus produced prior to the attachment of the chip 2, they can be formed according to a technique other than printing, for example metallisation by deposition.

This variant makes it possible to delay the attachment of the chip in the process of manufacturing the device in order not to be burdened by scrap from the contact area production operation.

Whatever the variant, it is possible to effect the printing of the communication interface (or part thereof) in several screen print passes, according to the pattern required.

Finally, it is possible to provide a fine protective film 20 covering the chip and part of the communication interface at the current feeds, close to the edges of the chip. This protective layer 20 can be deposited directly in the form of a thin film, or can be produced by spraying an agent in the liquid phase, such as a lacquer. The thickness of the protective film can thus remain less than around 10 microns, which makes it possible to comply with the standards with regard to the acceptable protrusion.

Naturally, it is also possible to produce, by the same technique, a communication interface for connecting at least one bump 8 on the chip 2 to at least one electrical element integrated into the card, the element being able to be any combination from amongst:

an antenna for exchanging data between the chip 2 and a radio reader for producing a contactless card, the antenna also being able to be a sensor for the electrical energy for supplying the chip;

at least one passive component such as a resistor, an inductor or a capacitor, forming for example an LC circuit;

at least one active component, such as a display, an energy source (for example a solar cell), etc; and

at least one other chip, this being able to be mounted on the support 16 of the card according to the technique used for the chip 2.

It should be noted that, by virtue of the fact that the method makes it possible not to place the chip in a cavity, it is possible to effect connections without being bothered by the difference in height between the chip and the contact areas to be connected.

This principle also makes it possible to produce a card with large chips, of the microprocessor type or other, which is not possible with the technology of attached chips according to the mosaic technology.

A second embodiment of the invention will now be described in which the techniques described previously are used for producing a module having several chips on the same support.

In the example illustrated in FIG. 6, which depicts in plan view a device after manufacture, the support 16 is also intended to constitute a smart card, the card including here four interconnected chips on the same face 16a. This type of card with several chips is generally known by the English term “multi-chip module”.

A first chip 2-1 groups together all the connection areas P serving to produce the interface with a reader with contact. This chip 2-1 and the connection areas P which surround it are therefore situated at the location of the support provided for the connection with a reader. The reader is designed to establish an ohmic contact with the areas P in order to exchange date with the card.

The first chip 2-1 is connected to three other chips 2-2, 2-3 and 2-4 by a set of interconnections, each interconnection connecting a bump on one chip to a bump on another. In FIG. 6, these interconnections are designated by the letter A followed by two figures separated by a dash, the latter designating respectively the last reference figure of the chips connected by the interconnection.

The interconnections A1-2 and A1-4 connect respectively a chip 2-2 and 2-4 directly to a contact area P which surrounds the first chip 2-1.

Each chip 2-1 to 2-4 is produced in the form of a respective wafer with the characteristics described with reference to FIGS. 2 and 3 (it is assumed here that these chips are all different). Like the first embodiment, the bumps on the chips are produced on the face 2b turned towards the protective substrate 4.

The aforementioned wafers are covered with an adhesive layer 10 as described with reference to FIG. 3.

They are then cut into sets of individual chips 14 each having a substrate 4 to the dimensions of the chip, the chip 2-1, . . . , or 2-4, the adhesive pads 6 and the adhesive layer 10 at the corners of the chip, as described with reference to FIG. 4.

Each assembly is attached to the surface of the support 16, at the location provided for the corresponding chip, with the adhesive layer 10 in contact with the face 16a of the support, as described with reference to FIG. 5.

Thus, for the present example, the four chips will have been attached and glued to the face 16a of the support at the locations indicated.

The protective substrate 4 of each assembly is then removed in the manner described with reference to FIG. 5a. This operation of removing the substrates 4 can be effected simultaneously once all the assemblies 14 are attached to the support 16.

Once the substrates have been removed, the communication interface is printed, this comprising all the connection areas P intended to come into contact with a reader, the current feeds A1 for the chip 2-1 and the interconnections A1-2, A2-3, A3-4 and A1-4.

The communication interface is produced in accordance with the technique described with reference to FIG. 5b and allows the same variants as those mentioned with regard to this figure.

In the example, the entire communication interface is produced by screen printing directly on the bumps on the chips 2-1 to 2-4 and on the surface 16a of the support 16. This printing is effected in a single pass by means of a conductive adhesive ink containing silver particles. Thus each chip has a metallisation at the contact bumps whose profile is similar to that depicted in FIG. 5b.

It is also possible to divide the production of the communication interface into several steps, at least one of which can take place before the attachment of the chips. This can notably be the case with the contact areas P and/or certain interconnections, for example the ones A2-3 and A3-4 which comprise several tracks close together. Thus any manufacturing fault at these parts of the communication interface can be noted before the chips are attached.

After the removal of the protective glass substrates 4, a fine protective layer is deposited on all the chips and interconnections, such as the film 20 described with reference to FIG. 5c.

Such an assembly of several chips on the same support, in this case on a flexible support, makes it possible to manufacture circuits of great complexity, notably a personal computer, to smaller formats. By way of example, a single card can comprise a microprocessor, a display and its control circuit, the whole interconnected.

A description will now be given of another aspect of the present invention according to which it is possible to effect a repair by replacement of one or more chips detected as being defective after they are attached to the communication interface.

This aspect will be described for the case of the production of a multiple-chip circuit as described and depicted in FIG. 6. However, it can also apply in a similar manner to cards with a single chip.

By way of illustration, it is assumed that a card thus composed of four chips 2-1 to 2-4 in one manufacturing batch proves defective during an end of production check.

Tests make it possible to locate the chip or chips in question according to the behaviour of the whole. In the context of the example, a test determines that the defect relates to the functioning of the chip 2-3 (FIG. 6). The defect may be situated either at the chip itself, this not having been tested previously or having been damaged subsequently, or at the interconnections between the bumps on the chip 2-3 and its communication interface.

FIG. 7a is a view in section along the axis VI-VI′ in FIG. 6. There can be seen the chips 2-2 and 2-3 on the face 16a of the support 16, the interconnection A2-3 connecting these two chips to respective bumps 8 and a portion of the interconnection A1-2 which connects the chip 2-2 to one of the contact areas P around the chip 2-1.

To replace the defective chip 2-3, initially it is pressed in with a punch 20 having a pressing face 20a to the format of the chip 2-3, or slightly larger (FIG. 7b). The pressing face 20a of the punch 20 can be heated in order to create a fusion of the material or generate a plastic phase thereof. The punch 20 pushes in the defective chip 2-3 and the part of the interconnection A2-3 around the bump 8 in the thickness of the card support 16. At the end of this operation, the defective chip 2-3 is entirely embedded in the support 16, the top surface of the chip 2-3 and of the interconnection part A2-3 around the bump 8 fitting flush with the surface 16a of the support. The aforementioned top surface can possibly be slightly recessed below the surface 16a of the support, as depicted in FIG. 7c. It will be noted that the pressing in ensures the rupture of the interconnection A2-3 around the bump 8. In this way, the defective chip 2-3 becomes electrically isolated from the other components of the card.

A new replacement chip 2-3′ is attached at the initial location of the defective chip according to the same technique as for the attachment of the other chips, as described with reference to FIGS. 4 and 5a. Thus the adhesive layer 10 associated with the replacement chip 2-3′ is put in contact with the top surface of the pressed-in chip 2-3 (FIG. 7d). The replacement chip 2-3′ is then at the same level as the defective chip 2-3 before it was pressed in, or slightly below this level.

Next, the portion or portions of the interconnection A2-3 which connects a corresponding bump 8 on the replacement chip 2-3′ is printed (FIG. 7e). The printing of this portion of the interconnection can be effected according to the same techniques as for the communication interface. Preferably, the newly printed portion slightly projects beyond the surface limits pressed in by the punch 20 in order to provide good continuity with the main part of the interconnection.

Naturally, the defective chip replacement technique can be applied to any other chip or several chips on one or other of the faces.

It is clear that the scope of the invention greatly exceeds the field of smart cards and applies to any circuit or assembly produced by attaching one or more chips to a support, notably a flexible support such as a card, film, etc.

Moreover, any combination described relating to one embodiment or variant also applies to another embodiment provided that it is technically achievable.

1. A method for manufacturing a device having a support associated with at least one microcircuit in the form of a chip, characterised in that it comprises the replacement of at least one chip with a defect either within it or its connection to the communication interface; this method including the steps consisting in:
pressing the chip to be replaced into the thickness of the support so that the top surface of the chip is flush with the surface (16a) of the support or is slightly recessed with respect to it and its connection with the communication interface is broken;
providing an assembly composed of a thin replacement chip held by a first face on a protective substrate and having on this first face at least one connection pad (8), and repeating for this replacement chip steps making provision b) for attaching the assembly to one face (16a) of the support, this second face of the chip, opposite to the first, opposite the face of the support, c) removing the protective substrate in order to expose the first face of the chip and d) producing at least part of the communication interface covering the first face of the chip at at least one connection pad and a surface portion (16a) of the support.

2. A method according to claim 1, characterised in that it includes a step a) prior to step b) which provides initially for the chip an assembly composed of a thin chip held by a first face on a protective substrate and having on this first face at least one connection pad (8).

3. A method according to claim 2, characterised in that the second face is attached to a surface portion of the face which is substantially in the general plane thereof.

4. A method according to claim 2 or 3, characterised in that it also includes at step a) the fact of providing an adhesive layer on the second face of the chip enabling the latter to be glued to the face of the support during step b).

5. A method according to one of claims 2 to 4, characterised in that it also includes a step of depositing a protective layer on at least one exposed part of the first face of the chip.

6. A method according to one of claims 2 to 5, characterised in that the entire communication interface necessary for the device is produced during the step of producing the communication interface, this including at least one connection area (P) and/or at least one interconnection for connecting the chip to the outside thereof.

7. A method according to one of claims 2 to 5, characterised in that at least part of the communication interface comprising a connection area (P) and/or at least one interconnection for connecting the chip to the outside thereof is produced prior to the step b) of attaching the chip to its support, step d) consisting in producing at least one connection link between at least one pad on the chip and a respective connection area or interconnection.

8. A method according to one of claims 2 to 7, characterised in that the communication interface is produced at step d) by printing.

9. A method according to claim 8, characterised in that the printing step is performed in a single pass.

10. A method according to one of claims 8 or 9, characterised in that the printing is carried out by screen printing.

11. A method according to any one of claims 8 to 10, characterised in that the printing is carried out with an adhesive ink containing conductive particles.

12. A method according to one of claims 7 to 11, characterised in that the part of the communication interface produced prior to the attachment of the chip is produced by screen printing.

13. A method according to one of claims 1 to 12, characterised in that each connection pad (8) is produced in the form of a bump on the first face of the chip.

14. A method according to one of claims 1 to 13, characterised in that the chip is produced by a so-called silicon on insulator (SOI) technology and has an overall thickness substantially equal to or less than 10 μm.

15. A method according to one of claims 1 to 14 for producing devices containing a plurality of interconnected chips, characterised in that step d) of producing at least part of the communication interface is carried out simultaneously for at least one group amongst the plurality of chips.

16. A device such as a smart card, electronic label etc including a support associated with at least one microcircuit in the form of a chip; characterised in that it comprises, on at least one of the faces of the support, at the chip or chips:
the chip having a first face, turned towards the outside vis-à-vis the support, having at least one connection pad and a second face glued to the face of the support; and
a communication interface covering at least one connection pad on the first face of the chip and a portion of the face of the support.

17. A device according to claim 16, manufactured according to the method of one of claims 1 to 15; characterised in that it also includes a protective layer on at least the first face of the chip.

18. A device according to claim 16 or 17, and manufactured according to the method of one of claims 1 to 15; characterised in that the surface above the chip has a protrusion relative to the general plane of the face of the support substantially equal to or less than 50 μm.
